(19) United States
(12) Patent Application Publication
(10) Pub. No.: US 2008/0151473 A1
(43) Pub. Date: Jun. 26, 2008

(54) ELECTRONIC COMPONENTS AND A METHOD OF MANUFACTURING THE SAME

(75) Inventor: Petri J. Korpi, Kangasala (FI)

Correspondence Address: MORGAN & FINNEGAN, L.L.P., 3 WORLD FINANCIAL CENTER, NEW YORK, NY, 10281-2101, US

(73) Assignee: NOKIA CORPORATION, Espoo (FI)

(21) Appl. No.: 11/613,430

(22) Filed: Dec. 20, 2006

(51) Int. Cl. H01G 9/00; H01L 21/00

(52) U.S. Cl. 361/523; 29/25.01; 29/729

(57) ABSTRACT

The present invention aims to overcome current problems with manufacturing electronic device, particularly when the device is manufactured using printing techniques to form elements of the device on a substrate. Here, any anomalies in printed electrode which result from the printing process are reduced or minimised by causing a portion of an electrode that forms the anomaly to be repelled from another electrode so that the electrodes form a desirable shape or contour prior to becoming cured.

The present invention relates to electronic components and a method of manufacturing electronic components. In particular, but not exclusively, the present invention relates to a capacitor and a method of manufacturing the capacitor.

Embodiments of the present invention are described herein with reference to a capacitor, although it is to be understood that embodiments of the present invention are not limited to capacitors or their mode of manufacture. The present invention can be applied to many different types of electronic components, such as transistors for instance.

Capacitors are well known electronic components, which are used in a multitude of electronic circuits or have a multitude of applications. Typically, a capacitor is formed of two electric plates or electrodes, spaced apart from one another such that an electric charge formed on one electrode can cause an opposite charge to build up on the other electrode.

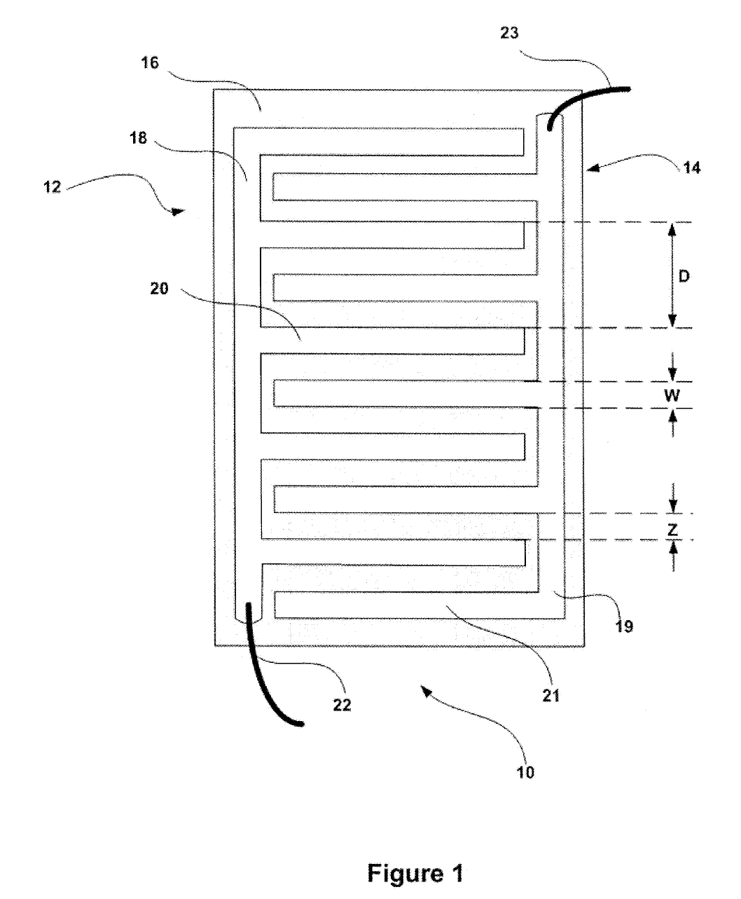

Referring now to FIG. 1, a conventional capacitor 10 is shown. The capacitor comprises two electrodes 12, 14 formed or disposed on a substrate 16. Each electrode comprises a spine element 18, 19 and a plurality of finger elements 20, 21 which extend on one side of the spine and generally at right angles thereto. The finger elements of one electrode are arranged to lie between complimentary finger elements of another electrode. Thus, the fingers are said to interdigitate. Electric contacts 22, 23 are formed at one end of each spine.

The figures of one electrode are spaced apart by a distance D and have a width W. The spacing Z between the fingers of respective electrode is thus given by

$$Z = \frac{( D - 2 W )}{2}$$

where the fingers are spaced symmetrically and the width W is equal for each of the electrode's fingers.

The electrodes of such a capacitor can be formed by printing electrically-conductive material onto a substrate. The printing process might comprise any of ink-jet printing, screen printing, offset printing, gravure printing, xerographic printing, flexographic printing, stamping, or the like. Thus, during the printing process, the material which is used to form the capacitor's electrode is printable, and typically in a liquid form or in a liquid suspension.

The liquid might comprise ink, into which conductive particles have been mixed. The conductive material typically comprises particles of metal, such as copper or aluminium, suspended in a solvent or liquid. The particles are referred to as so-called “nano-particles”. The particles are typically generally spherical in shape with a diameter of roughly 2-5 nm and are coated in a polymer layer. These particles are ‘grown’ from atoms, so that the final shape of the particle is undefined and may not be smoothly spherical. The polymer acts to provide many benefits, including ensuring that the particles are more evenly distributed throughout the liquid suspension once printed on the substrate. Furthermore, the polymer coating helps to prevent the nano-particles from sticking together and forming clumps of particles.

After the electrodes are printed they can be cured. The curing process involves applying heat to the printed electrodes to drive off any residual liquid suspension, thereby leaving the conductive nano-particles on the substrate's surface. Furthermore, the heat used for curing the electrode can be arranged to cause the polymer coating of the nano-particles to melt or evaporate thereby resulting in the nano-particles coming into contact with one another and form an electrically conductive electrode. The electric contacts can then be attached to the spine by soldering, or the like.

There are several problems or limitations with current methods of forming electronic components in this way. For instance, it is presently not possible to form two or more juxtaposed electrodes which have a spacing Z of less than 1 μm apart. In addition, using current techniques it is not possible to print an electrode having a line width W of less than 1 μm. This can affect and limit the electrical characteristics of components made using this method.

The current printing processes do not allow for the finger elements of the capacitor to be placed at a desirable or optimised distance from one another. Neither is it currently possible to accurately control how the ink is deposited onto the substrate. For instance, the edges of the fingers might be inconsistent after printing and not follow a straight line, within specified tolerances, or the finger elements might be printed inaccurately. In other words, portions of the electrode might be formed unevenly along the edge of the electrode thereby forming protrusions extending from the edge, for instance.

Furthermore, it is desirable to minimise the spacing between the electrodes in order to achieve the desired electrical characteristic for the electronic device. However, using current techniques, it is not considered possible to print the electrodes on the substrate having spacing of less than 1 μm without there being an undesirably high probability that the electrodes might contact one another. The contact of one electrode with another is undesirable because the resulting electronic component (in this case a capacitor) is highly likely to malfunction.

Further still, the spacing between finger elements of such capacitors needs to be controlled to try and ensure accurate and consistent spacing. If this is not achieved, then the electrical characteristics of the device are affected, resulting in a poor consistency of characteristics across a batch of manufactured components. As a result, a high proportion of devices might be discarded because they do not pass a quality control.

Therefore, there is presently a need to improve the manufacturing techniques of electronic components. The improved technique should result in improved characteristics of electronic components and/or reduced component size.

The present invention aims to address the problems of the prior art discussed above. Furthermore, the present invention might solve other problems not considered here. Any anomalies in an electrode which might result from the printing process can be reduced or minimised by causing a portion of a portion of the electrode that forms the anomaly to be repelled from another electrode so that the electrodes of the device form a desirable shape or follow a desirable contour prior to becoming cured.

More precisely, an aspect of the present invention provides a method of manufacturing an electronic device, said device comprising at least two electrical components, the method comprising: disposing a first electrical component on a substrate, disposing a second electrical component on said substrate at a position juxtaposed to said first electrical component, and causing said first and second electrical components to repel one another; wherein the first and second electrical components are in a liquid form during the disposing steps.

In addition, the disposing of the first and second electrical components can comprise printing said first and second components respectively onto the substrate.

In addition, the method can further comprise a step of curing the first and second electrical components, which occurs after the step of causing the electrical components to repel one another.

In addition, the step of causing the electrical components to repel one another can comprise the application of an electric charge onto the first and second electrical components.

In addition, the first electrical component can comprise particles of conductive material suspended in a first liquid, the second electrical component can comprise particles of conductive material suspended in a second liquid, wherein the first and second liquids are immiscible.

In addition, the first and second liquids can be hydrophobic with respect to one another.

In addition, the step of causing said first and second electrical components to repel one another can occur due to the properties of the first and second liquids.

In addition, the method can further comprise disposing a boundary layer between the first and second electrical components, wherein the boundary layer acts to separate the first and second electrical components. The boundary layer should be an insulating layer to prevent a short circuit between the electrical components of the device.

Another aspect of the present invention provides a method of manufacturing a capacitor having at least two interdigitating electrodes, comprising; printing a first electrode of the capacitor on a substrate, printing a second electrode of the capacitor on a substrate at a position juxtaposed to the first electrode, causing the first and second electrodes to repel one another, and curing the electrodes; wherein the first and second electrodes are in a liquid form during the step of causing the electrodes to repel one another.

In addition, the step of causing the first and second electrodes to repel one another can comprise applying an electric charge to the first and second electrodes so that conductive elements in the electrodes repel one another.

In addition, in their liquid form, the first electrode can comprise conductive particles suspended in a first solvent, the second electrode can comprise conductive particle suspended in a second solvent, and the first and second solvents can be immiscible and hydroscopic with respect to one another.

In addition, the step of causing the first and second electrodes to repel one another can occur due to physical properties of the first and second solvents.

In addition, the method can further comprise, printing a third liquid boundary layer between the first and second electrodes, wherein the boundary layer acts to separate the first and second electrodes. The third liquid boundary layer can comprise a third liquid which is immiscible with the first and second solvents. In this instance, the first and second solvents can be the same substance.

A further aspect of the present invention provides an electrical component comprising two or more conductive elements, said elements being deposited on a substrate by a printing process, wherein the elements are in a fluid form during the printing process so that each element can be repelled from the other element.

In addition, during the printing process, a first element can comprise a plurality of conductive particles suspended in a first solvent, a second element can comprise a plurality of conductive particles suspended in a second solvent, and the first and second solvents are immiscible and hydroscopic with respect to one another.

In addition, the two or more conductive elements can be spaced about and define a gap therebetween, and wherein the width of the gap is less than 1 micron. Furthermore, the width of the gap can be less than 800 nm. Still further, the width of the gap can be less than 500 nm.

A yet further aspect of the present invention provides apparatus for manufacturing an electronic device, comprising; a printer for printing a first and a second electrically conducting element of the electronic device onto a substrate, wherein the first electrically conducting element comprises a plurality of conductive particles suspended in a first solvent, a second element comprises a plurality of conductive particles suspended in a second solvent, and the first and second solvents are immiscible and hydroscopic with respect to one another.

In addition, the apparatus can comprise a charge applicator for applying an electric charge to the first and second electrically conducting elements whilst the elements are in a fluid state.

In addition, the apparatus can comprise a curer for curing the electronic device.

In addition, the printer can be arranged to print a dielectric boundary layer adapted to separate the first and a second electrically conducting elements.

Another aspect of the present invention provides apparatus for manufacturing an electronic device, comprising; a printer for printing a first and a second electrically conducting element of the electronic device onto a substrate wherein the first and second electrically conducting element are in a fluid state during the printing process, and a charge applicator for applying an electric charge to the first and second electrically conducting elements whilst the elements are in a fluid state.

In addition, the apparatus can further comprise a curer for curing the electronic device after the charge has been applied by the charge applicator.

In addition, the printer can be arranged to print a third non-conductive element adapted to separate the first and second electrically conducting elements.

A further aspect of the present invention provides a method of manufacturing an electronic device, said device comprising at least two electrical portions, the method comprising: disposing a first electrical portion on a substrate, and disposing a second electrical portion on said substrate at a position juxtaposed to said first electrical portion; wherein the first and second electrical portions are in a liquid form during the disposing steps and the first and second portions are hydrophobic with respect to one another.

In addition, the disposing of the first and second electrical portions can comprise printing said first and second portions respectively onto the substrate.

In addition, the method can further comprise the step of causing the electrical portions to repel one another by applying an electric charge onto the first and second electrical portions. Alternatively or in addition, the method can further comprise the step of curing the first and second electrical portions after the step of causing the electrical portions to repel one another.

In addition, the first electrical portion can comprise particles of conductive material suspended in a first liquid, the second electrical portion comprises particles of conductive material suspended in a second liquid, and wherein the first and second liquids are immiscible.

In addition, the method can further comprise, disposing a boundary layer on the substrate between the first and second electrical portions, wherein the boundary layer acts to separate the first and second electrical portions.

Other embodiments and/or aspects of the present invention will become apparent to the skilled person. Embodiments of the present invention are now described below by way of example, and with reference to the drawings, of which:

FIG. 1 shows a schematic view of a conventional capacitor formed by using a printing technique;

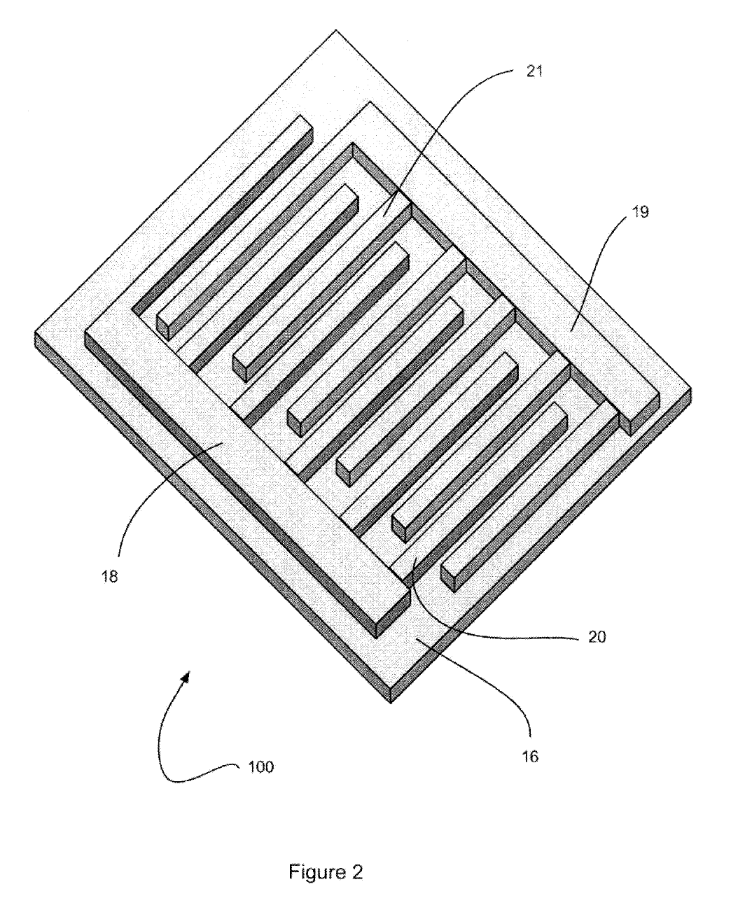

FIG. 2 shows a schematic of a capacitor embodying the present invention;

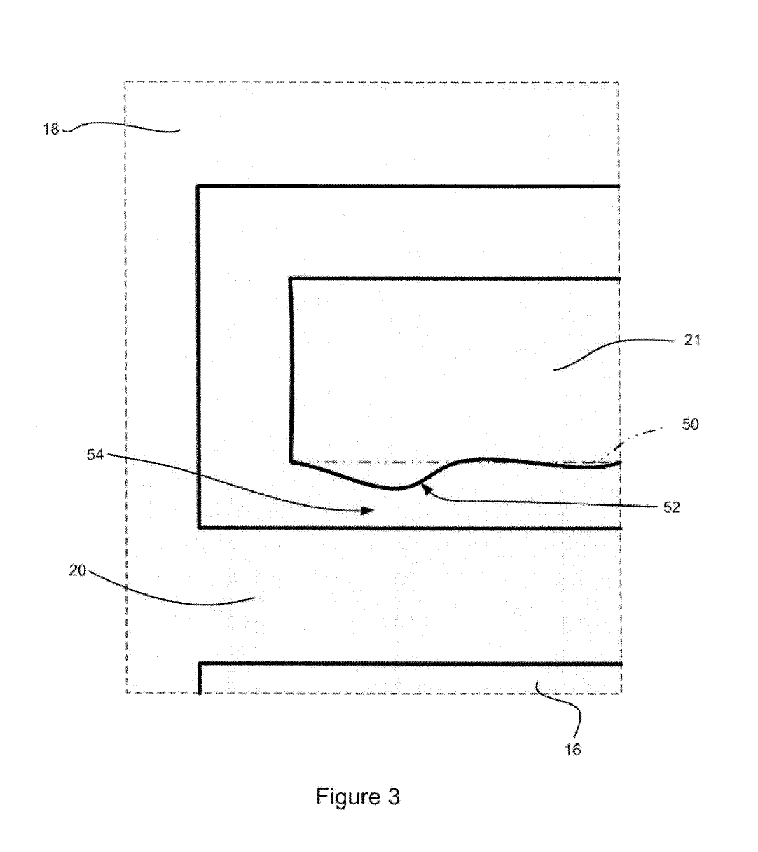

FIG. 3 is a schematic diagram showing a portion of an electronic device embodying the present invention; and

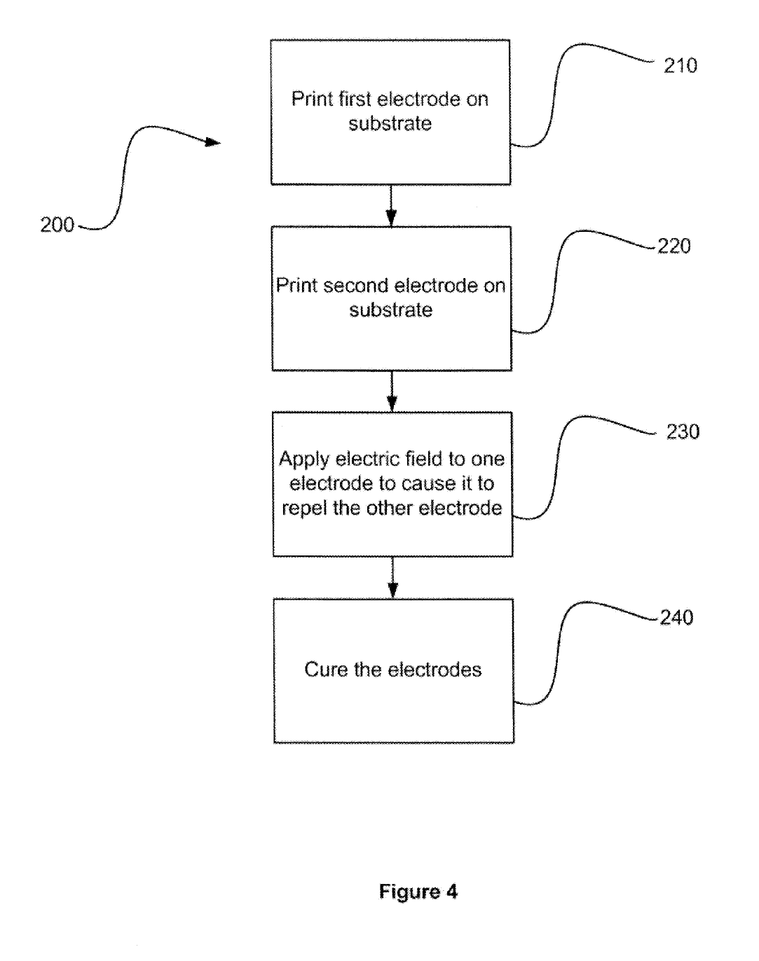

FIG. 4 is a flow chart of a method of manufacturing an electronic device embodying the present invention.

Reference will now be made in detail to embodiments of the present invention, examples of which are illustrated in the accompanying drawings, wherein like reference numerals refer to the like elements throughout. The embodiments are described below in order to explain the present invention by referring to the figures.

Referring now to FIG. 2, a capacitor 100 embodying the present invention is shown. The capacitor is formed by printing electrodes onto a substrate. However, during the manufacturing process, the electrodes are repelled from one another whilst still in a fluid state. As a result, any anomalies of the electrode's shape caused by the printing process (or however) can be reduced, minimised or eliminated.

The anomalies might be in the form of an uneven deposit of material on the substrate, which causes the edge of the electrode to have an undesirable profile. For instance, where it is desirable for the electrode to have a straight edge, the resultant electrode might have anomalies which are protrusions of material extending from the desired straight edge. In a worse case scenario, this type of anomaly can bridge the gap between the electrodes thereby causing a short circuit of the electronic device.

In another form an anomaly might comprise unevenly distributed particles throughout the material printed on the substrate. When this occurs, the resulting electrode that is formed after the curing process can have gaps or holes where no or very few conductive particles are present. As a result, the electrical characteristics of the electrode may be undesirable.

Referring to FIG. 3, an enlarged area of an electronic device is shown. Here, a portion of a first and second electrode 20, 21 are shown. During the printing process, electrode 20 has formed the desirable shape on the substrate 16. However, electrode 21 has formed with an undesirable shape. (The broken line 50 shows the desirable shape). A protrusion or anomaly 52 is shown where a portion of the electrode extends in to the gap 54 between the electrodes by a significant amount.

If this protrusion were left unchecked, then the electrical characteristics of the resulting electronic device might be affected to an extent where the device fails quality control checks and is rejected. However, if the effects of this anomaly can be reduced or minimised, then the device would have a higher probability of passing quality control checks. Thus, the economic benefits to a device manufacturer can be realised. Furthermore, having the ability to reduce or minimise such anomalies can advantageously result in the manufacture of electronic devices whereby the gap between the electrodes is reduced from current limitations, thereby increasing or improving the capabilities of such devices, and/or reducing the physical size of the devices.

The material in each of the electrodes can be repelled from one another using different techniques. Some examples of these techniques are now presented.

In a first embodiment, the repulsion occurs as a result of the physical properties of solvents or liquids used during the printing process. Here, the first electrode is formed of ink comprising a first liquid, and the second electrode is formed of ink comprising a second liquid. Here, an ink is taken to mean a liquid or semi-liquid (such as a wax) which can be formed of a carrier liquid in which other liquids (such as dyes) or particles can be mixed or suspended.

The first and second printing liquids (that is, the ink carrier liquids) should be immiscible and/or hydroscopic with respect to one another. In other words, the liquids should not be able to mix. Thus, if a drop of one solvent contacts another, then it should not be possible for a mixing or boundary layer to form between the two liquids: the liquids are repelled from one another. The repelling force might be as a result of relatively high intermolecular (van der Waals) forces associated with each of the liquids used in the printing process. These forces result in a surface tension associated with the surface of the liquids thereby having properties which prevent the liquids from mixing, or forming a single drop when two or more drops are brought together. In other words, a so-called “beading effect” occurs.

Examples of suitable solvents or liquids used for the inks include tetradecane, isopropyl alcohol and some vaxes that are liquids in low temperatures can be used as solvents. The viscosity of the solvent is such that the fluidity is quite high so that it forms a smooth surface when the ink is deposited to the substrate.

In an alternative method, once the electrodes have been printed they can be repelled from one another by utilising electrostatic forces. For instance, an electric charge can be applied to the electrodes whilst they are in the fluid or liquid form, causing the electrode to be repelled from one another. Thus, a force applied to any anomalies formed by material, which has been undesirably formed in the gap between electrodes, can be greater than the force applied to the main portion of the electrode. As a result, in this case, the anomaly is forced out of the gap by an extent, thereby reducing or minimising the anomaly's size or the amount by which the anomaly extends into the gap.

Using this method, it is possible to move or reduce the number of conductive particles held in suspension out of an area where the anomaly has formed, thereby resulting in the anomaly comprising just the solvent or suspension fluid. Alternatively, a sufficient portion of the conductive particles can be moved out of the anomaly such that, when the device is cured, the conductive particles in the area of the anomaly are isolated from one another and do not form a conductive portion of the electrode.

This method of manufacturing an electronic component embodying the present invention is represented in FIG. 4. Here, a flow chart showing the steps 200 of manufacture is shown. The first electrode is printed 210 onto the substrate and then the second electrode is printed 220 on to the substrate. An electric charge is applied 230 to the electrodes to cause the electrode to repel one another. The electrodes are then cured 240 to form an electronic component. The curing process can take place with or without the repelling electric charge on the electrodes. In some circumstances, it might be desirable to maintain the repelling electric charge on the electrodes as the capacitor is cured.

In another embodiment, a third liquid is printed between the electrode lines in order to maintain a separation between the electrodes. The third liquid acts as a barrier between the liquids forming the electrodes. The third liquid should be immiscible with the other liquids and should not contain any conductive particles. In this embodiment, the two or more electrodes can be printed using the same liquid suspension.

A combination of the above-described methods can be used to further enhance the repulsion of electrodes.

Using these techniques, or combinations thereof, it is possible to manufacture electronic devices having gaps or spacing Z (with reference to FIG. 1, for illustration purposes) between electrodes of less than 1 μm. Furthermore, it is possible to manufacture electronic devices where the electrode's line width W is less than 1 μm. Indeed, devices where Z>800 nm, and W>800 nm are possible, using the techniques described. Furthermore, devices where Z>500 nm, and W>500 nm are possible, using the techniques described.

Embodiments of the invention are described above with reference to a capacitor. It is understood that the invention is not limited to such devices and can be equally applied to other electronic devices. Furthermore, the embodiments described above refer to a capacitor having a single metallic or metallised layer which forms an electrode of the capacitor. The electrodes might, in addition, be formed of a multiple layers of metallic or conductive substances formed on top of one another and spaced apart by a dielectric layer. In this instance, the capacitance between the electrodes or interdigitating fingers consists of the capacitance of every metallic layer's capacitance, from one terminal to the other.

Other aspects of the present invention will become apparent to the skilled person without leaving the scope and spirit of the invention as defined in the claims, or their equivalents. For instance, it is appreciated that other means of repelling one electrode from another may be realized.

1. A method of manufacturing an electronic device, said device comprising at least two electrical portions, the method comprising:
disposing a first electrical portion on a substrate,
disposing a second electrical portion on said substrate at a position juxtaposed to said first electrical portion, and
causing said first and second electrical portions to repel one another;
wherein the first and second electrical portions are in a liquid form during the disposing steps.

2. A method according to claim 1, wherein the disposing of the first and second electrical portions comprises printing said first and second portions respectively onto the substrate.

3. A method according to claim 2, further comprising the step of curing the first and second electrical portions after the step of causing the electrical portions to repel one another.

4. A method according to claim 1, wherein the step of causing the electrical portions to repel one another comprises applying an electric charge onto the first and second electrical portions.

5. A method according to claim 1, wherein
the first electrical portion comprises particles of conductive material suspended in a first liquid,
the second electrical portion comprises particles of conductive material suspended in a second liquid, and
wherein the first and second liquids are immiscible.

6. A method according to claim 5, wherein the first and second liquids are hydrophobic with respect to one another.

7. A method according to claim 5, wherein the step of causing said first and second electrical portions to repel one another occurs due to the properties of the first and second liquids.

8. A method according to claim 1, further comprising, disposing a boundary layer on the substrate between the first and second electrical portions, wherein the boundary layer acts to separate the first and second electrical portions.

9. A method of manufacturing a capacitor having at least two interdigitating electrodes, comprising;
printing a first electrode of the capacitor on a substrate,
printing a second electrode of the capacitor on a substrate at a position juxtaposed to the first electrode,
causing the first and second electrodes to repel one another, and
curing the electrodes;
wherein the first and second electrodes are in a liquid form during the step of causing the electrodes to repel one another.

10. A method according to claim 9, wherein the step of causing the first and second electrodes to repel one another comprises applying an electric charge to the first and second electrodes so that conductive elements in the electrodes repel one another.

11. A method according to claim 9, wherein, in their liquid form, the first electrode comprises conductive particles suspended in a first solvent, the second electrode comprises conductive particle suspended in a second solvent, and the first and second solvents are immiscible and hydroscopic with respect to one another.

12. A method according to claim 11, wherein the step of causing the first and second electrodes to repel one another occurs due to physical properties of the first and second solvents.

13. A method according to claim 11, further comprising, printing a third liquid boundary layer between the first and second electrodes, wherein the boundary layer acts to separate the first and second electrodes.

14. A method according to claims 13, wherein the third liquid boundary layer comprises a third liquid which is immiscible with the first and second solvents.

15. An electrical component comprising two or more conductive elements, said elements being deposited on a substrate by a printing process, wherein the elements are in a fluid form during the printing process so that each element can be repelled from the other element.

16. An electrical component according to claim 15, wherein, during the printing process, a first element comprises a plurality of conductive particles suspended in a first solvent, a second element comprises a plurality of conductive particles suspended in a second solvent, and the first and second solvents are immiscible and hydroscopic with respect to one another.

17. An electrical component according to claim 15, wherein the two or more conductive elements are spaced about and define a gap therebetween, and wherein the gap is less than 1 micron.

18. An electrical component according to claim 15, wherein the two or more conductive elements are spaced about and define a gap therebetween, and wherein the gap is less than 800 nm.

19. An electrical component according to claim 15, wherein the two or more conductive elements are spaced about and define a gap therebetween, and wherein the gap is less than 500 nm.

20. Apparatus for manufacturing an electronic device, comprising;
a printer for printing a first and a second electrically conducting element of the electronic device onto a substrate,
wherein the first electrically conducting element comprises a plurality of conductive particles suspended in a first solvent, a second element comprises a plurality of conductive particles suspended in a second solvent, and the first and second solvents are immiscible and hydroscopic with respect to one another.

21. Apparatus according to claim 17, further comprising a charge applicator for applying an electric charge to the first and second electrically conducting elements whilst the elements are in a fluid state.

22. Apparatus according to claim 17, further comprising a curer for curing the electronic device.

23. Apparatus according to claim 17, wherein the printer is arranged to print a dielectric boundary layer adapted to separate the first and a second electrically conducting elements.

24. Apparatus for manufacturing an electronic device, comprising;
a printer for printing a first and a second electrically conducting element of the electronic device onto a substrate wherein the first and second electrically conducting element are in a fluid state during the printing process, and
a charge applicator for applying an electric charge to the first and second electrically conducting elements whilst the elements are in a fluid state.

25. Apparatus according to claim 24, further comprising a curer for curing the electronic device after the charge has been applied by the charge applicator.

26. Apparatus according to claim 14, wherein the printer is arranged to print a third non-conductive element adapted to separate the first and second electrically conducting elements.

27. A method of manufacturing an electronic device, said device comprising at least two electrical portions, the method comprising:
disposing a first electrical portion on a substrate, and
disposing a second electrical portion on said substrate at a position juxtaposed to said first electrical portion;
wherein the first and second electrical portions are in a liquid form during the disposing steps and the first and second portions are hydrophobic with respect to one another.

28. A method according to claim 27, wherein the disposing of the first and second electrical portions comprises printing said first and second portions respectively onto the substrate.

29. A method according to claim 27, further comprising the step of causing the electrical portions to repel one another by applying an electric charge onto the first and second electrical portions.

30. A method according to claim 27, further comprising the step of curing the first and second electrical portions after the step of causing the electrical portions to repel one another.

31. A method according to claim 27, wherein
the first electrical portion comprises particles of conductive material suspended in a first liquid,
the second electrical portion comprises particles of conductive material suspended in a second liquid, and
wherein the first and second liquids are immiscible.

32. A method according to claim 27, further comprising, disposing a boundary layer on the substrate between the first and second electrical portions, wherein the boundary layer acts to separate the first and second electrical portions.
